(19) United States
(12) Patent Application Publication
(10) Pub. No.: US 2025/0070744 A1
(43) Pub. Date: Feb. 27, 2025

(54) ACOUSTIC WAVE DEVICE

(71) Applicant: Murata Manufacturing Co., Ltd., Nagaokakyo-shi, Kyoto-fu (JP)

(72) Inventor: Sho NAGATOMO, Nagaokakyo-shi (JP)

(21) Appl. No.: 18/945,931

(22) Filed: Nov. 13, 2024

Related U.S. Application Data
(63) Continuation of application No. PCT/JP2023/018839, filed on May 19, 2023.
(60) Provisional application No. 63/343,653, filed on May 19, 2022.

(51) Int. Cl. H03H 9/02; H10N 30/853; H10N 30/87; H10N 30/88

(52) U.S. Cl. CPC H03H 9/02031; H10N 30/8542; H10N 30/871; H10N 30/88

(57) ABSTRACT

An acoustic wave device includes resonators including a support with a hollow portion, a piezoelectric layer, and a functional electrode. The piezoelectric layer is on one main surface of the support and includes first and second main surfaces. The functional electrode is on at least one main surface of the piezoelectric layer and partially matches the hollow portion as seen in a thickness direction of the piezoelectric layer. The resonators include first and second resonators. The functional electrode of the first resonator includes at least one pair of a first and second electrode on the same main surface of the piezoelectric layer. The functional electrode of the second resonator includes upper and lower surface electrodes on the first and second main surfaces of the piezoelectric layer.

### CROSS REFERENCE TO RELATED APPLICATIONS

This application claims the benefit of priority to Provisional Application No. 63/343,653 filed on May 19, 2022 and is a Continuation application of PCT Application No. PCT/JP2023/018839 filed on May 19, 2023. The entire contents of each application are hereby incorporated herein by reference.

### BACKGROUND OF THE INVENTION

### 1. Field of the Invention

The present disclosure relates to acoustic wave devices.

### 2. Description of the Related Art

Japanese Unexamined Patent Application Publication No. 2012-257019 discloses an acoustic wave device.

The acoustic wave device disclosed in Japanese Unexamined Patent Application Publication No. 2012-257019 may be formed as a ladder filter. To form a high-capacitance filter, the use of large resonators is required. This may increase the size of the acoustic wave device.

### SUMMARY OF THE INVENTION

Example embodiments of the present invention reduce the size of acoustic wave devices.

An acoustic wave device according to an example embodiment of the present invention includes multiple resonators. The multiple resonators include a support, a piezoelectric layer, and a functional electrode. The support includes a hollow portion on a side of one main surface of the support. The piezoelectric layer is provided on one main surface of the support and includes first and second main surfaces. The functional electrode is provided on at least one of the first and second main surfaces of the piezoelectric layer so as to at least partially match the hollow portion as seen in a thickness direction of the piezoelectric layer. The multiple resonators include first and second resonators. The functional electrode of the first resonator includes at least one pair of a first electrode and a second electrode on a same main surface of the piezoelectric layer. The functional electrode of the second resonator includes an upper surface electrode on the first main surface of the piezoelectric layer and a lower surface electrode on the second main surface of the piezoelectric layer.

According embodiments of the present invention, it is possible to reduce the size of acoustic wave devices.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view of an acoustic wave device according to an example embodiment of the present invention.

FIG. 1B is a plan view of an electrode structure of an example embodiment of the present invention.

FIG. 2 is a sectional view taken along line II-II in FIG. 1A.

FIG. 3A is a schematic sectional view for explaining a Lamb wave propagating through a piezoelectric layer in a comparative example.

FIG. 3B is a schematic sectional view for explaining a bulk wave of a thickness shear primary mode propagating through a piezoelectric layer in an example embodiment of the present invention.

FIG. 4 is a schematic sectional view for explaining the amplitude direction of a bulk wave of a thickness shear primary mode propagating through a piezoelectric layer in an example embodiment of the present invention.

FIG. 5 is a graph illustrating an example of the resonance characteristics of an acoustic wave device of an example embodiment of the present invention.

FIG. 6 is a graph illustrating, regarding an acoustic wave device of an example embodiment of the present invention, the relationship between d/2p, where d is the average thickness of the piezoelectric layer and p is the center-to-center distance or the average center-to-center distance between adjacent electrodes, and the fractional bandwidth of the acoustic wave device as a resonator.

FIG. 7 is a schematic plan view illustrating an example in which a pair of electrodes is provided in an acoustic wave device of an example embodiment of the present invention.

FIG. 8 is a reference graph illustrating an example of the resonance characteristics of an acoustic wave device of an example embodiment of the present invention.

FIG. 9 is a diagram illustrating the relationship between the fractional bandwidth of many acoustic wave resonators provided based on an acoustic wave device of an example embodiment of the present invention and the amount of phase shift of the impedance of a spurious response normalized at about 180 degrees as the magnitude of the spurious response.

FIG. 10 is a graph illustrating the relationships between d/2p, the metallization ratio MR, and the fractional bandwidth.

FIG. 11 is a diagram illustrating a map of the fractional bandwidth with respect to the Euler angles (0°, θ, ψ) of LiNbO₃ in a case in which d/p approaches as close to 0 as possible.

FIG. 12 is a partial cutaway perspective view for explaining an acoustic wave device according to an example embodiment of the present invention.

FIG. 13 is a schematic plan view illustrating a portion of an example of an acoustic wave device according to an example embodiment of the present invention.

FIG. 14 is a sectional view taken along line XIV-XIV.

FIG. 15 is a circuit diagram of an acoustic wave device according to an example embodiment of the present invention.

FIG. 16 is a graph illustrating the frequency characteristics of an acoustic wave device according to an example embodiment of the present invention.

FIG. 17 is a graph illustrating coupling factors of resonators of an acoustic wave device according to an example embodiment of the present invention.

FIG. 18 is a schematic plan view illustrating a portion of a modified example of an acoustic wave device according to an example embodiment of the present invention.

FIG. 19 is a sectional view taken along line XIX-XIX.

### DETAILED DESCRIPTION OF THE EXAMPLE EMBODIMENTS

Example embodiments of the present invention will be described below in detail with reference to the drawings. The example embodiments are not provided to restrict the disclosure. The individual example embodiments described in the disclosure are only examples and the configurations described in different example embodiments may be partially replaced by or combined with each other. Regarding modified examples and second and subsequent example embodiments, reference will be given only to the configuration different from that of a first example embodiment while an explanation of the same or corresponding configuration as the first example embodiment is omitted. Similar advantages obtained by the same or similar configurations are not repeated every time an example embodiment is explained.

### EXAMPLE EMBODIMENTS

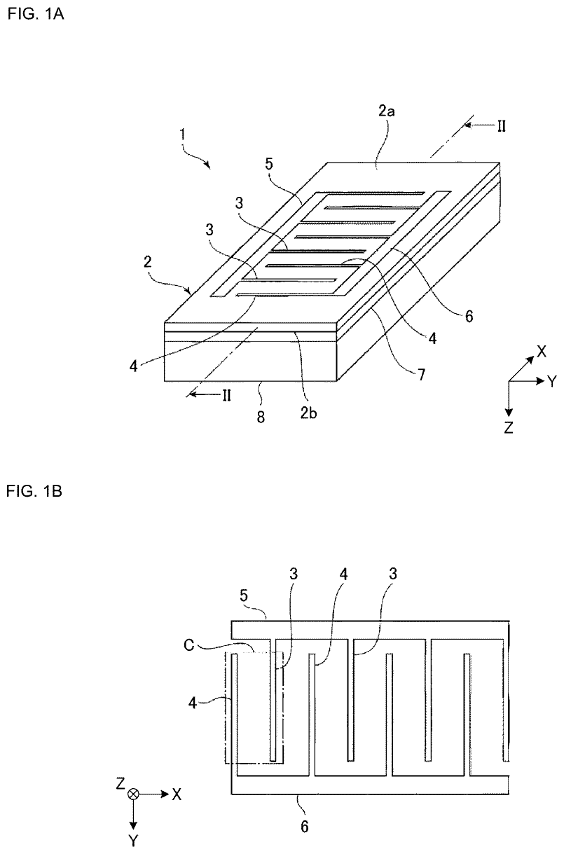

FIG. 1A is a perspective view of an acoustic wave device according to an example embodiment of the present invention. FIG. 1B is a plan view of the electrode structure of the present example embodiment.

An acoustic wave device 1 of the present example embodiment includes a piezoelectric layer 2 made of LiNbO₃, for example. The piezoelectric layer 2 may alternatively be made of LiTaO₃, for example. The cut-angles of LiNbO₃ or LiTaO₃ in the first example embodiment are Z-cut, for example, but may be rotated Y-cut or X-cut. Preferably, the cut-angles of LiNbO₃ or LiTaO₃ have a propagation orientation of Y-propagation about ±30° and X-propagation about ±30°, for example.

The thickness of the piezoelectric layer 2 is not restricted to a particular thickness, but is, for example, preferably about 50 nm to about 1000 nm to effectively excite the thickness shear primary mode.

The piezoelectric layer 2 includes first and second main surfaces 2a and 2b facing each other in the Z direction. On the first main surface 2a, electrode fingers 3 and 4 are provided. The electrode fingers 3 and 4 may be disposed on the second main surface 2b.

The electrode finger 3 is an example of a “first electrode”, while the electrode finger 4 is an example of a “second electrode”. In FIGS. 1A and 1B, the multiple electrode fingers 3 are multiple “first electrodes” connected to a first busbar 5, while the multiple electrode fingers 4 are multiple “second electrodes” connected to a second busbar 6. The multiple electrode fingers 3 and the multiple electrode fingers 4 are interdigitated with each other. This defines an IDT (Interdigital Transducer) electrode including the electrode fingers 3 and 4 and the first and second busbars 5 and 6.

The electrode fingers 3 and 4 have a rectangular or substantially rectangular shape and have a longitudinal direction. An electrode finger 3 and an adjacent electrode finger 4 face each other in a direction perpendicular or substantially perpendicular to this longitudinal direction. The longitudinal direction of the electrode fingers 3 and 4 and the direction perpendicular or substantially perpendicular to the longitudinal direction of the electrode fingers 3 and 4 are both directions intersecting with the thickness direction of the piezoelectric layer 2. It can thus be said that an electrode finger 3 and an adjacent electrode finger 4 face each other in a direction intersecting with the thickness direction of the piezoelectric layer 2. In the following description, an explanation may be provided such that the thickness direction of the piezoelectric layer 2 is the Z direction (or a first direction), the longitudinal direction of the electrode fingers 3 and 4 is the Y direction (or a second direction), and the direction perpendicular or substantially perpendicular to the longitudinal direction of the electrode fingers 3 and 4 is the X direction (or a third direction).

The electrode fingers 3 and 4 may extend in a direction perpendicular or substantially perpendicular to the longitudinal direction of the electrode fingers 3 and 4 shown in FIGS. 1A and 1B. That is, the electrode fingers 3 and 4 may extend in the extending direction of the first busbar 5 and the second busbar 6 shown in FIGS. 1A and 1B. In this case, the first busbar 5 and the second busbar 6 extend in the extending direction of the electrode fingers 3 and 4 shown in FIGS. 1A and 1B. Multiple pairs of electrode fingers 3 and electrode fingers 4, each pair including an electrode finger 3, which is connected to one potential, and an electrode finger 4, which is connected to the other potential, adjacent to each other, are arranged in the direction perpendicular or substantially perpendicular to the longitudinal direction of the electrode fingers 3 and 4.

“Electrode fingers 3 and 4 adjacent to each other” refers to, not that the electrode fingers 3 and 4 are disposed to directly contact each other, but that the electrode fingers 3 and 4 are disposed with a space therebetween. When electrode fingers 3 and 4 are adjacent to each other, an electrode connected to a hot electrode and an electrode connected to a ground electrode, including the other electrode fingers 3 and 4, are not disposed between the adjacent electrode fingers 3 and 4. The number of pairs of adjacent electrode fingers 3 and 4 is not necessarily an integral number and may be 1.5 or 2.5, for example.

The center-to-center distance, that is, the pitch, between the electrode fingers 3 and 4 is, for example, preferably about 1 μm to about 10 μm. The center-to-center distance between the electrode fingers 3 and 4 is a distance from the center of the width of the electrode finger 3 in the direction perpendicular or substantially perpendicular to the longitudinal direction of the electrode finger 3 to that of the electrode finger 4 in the direction perpendicular or substantially perpendicular to the longitudinal direction of the electrode finger 4.

When at least one of the number of electrode fingers 3 and the number of electrode fingers 4 is plural (e.g., when 1.5 or more pairs of electrode fingers 3 and 4, each pair being formed by an electrode finger 3 and an electrode finger 4, are provided), the center-to-center distance between the electrode fingers 3 and 4 is the average value of those between adjacent electrode fingers 3 and 4 of the 1.5 or more pairs.

The width of each of the electrode fingers 3 and 4, that is, the dimension in the facing direction of the electrode fingers 3 and 4, is, for example, preferably about 150 nm to about 1000 nm. The center-to-center distance between the electrode fingers 3 and 4 is a distance from the center of a dimension (width) of the electrode finger 3 in the direction perpendicular or substantially perpendicular to the longitudinal direction of the electrode finger 3 to that of the electrode finger 4 in the direction perpendicular or substantially perpendicular to the longitudinal direction of the electrode finger 4.

In the first example embodiment, since a Z-cut piezoelectric layer is used, the direction perpendicular or substantially perpendicular to the longitudinal direction of the electrode fingers 3 and 4 is a direction perpendicular or substantially perpendicular to the polarization direction of the piezoelectric layer 2. However, this is not the case if a piezoelectric body of another cut angle is used as the piezoelectric layer 2. “Being perpendicular” does not necessarily mean being exactly perpendicular, but may mean being substantially perpendicular. For example, the angle between the direction perpendicular to the longitudinal direction of the electrode fingers 3 and 4 and the polarization direction may be in a range of about 90°±10°.

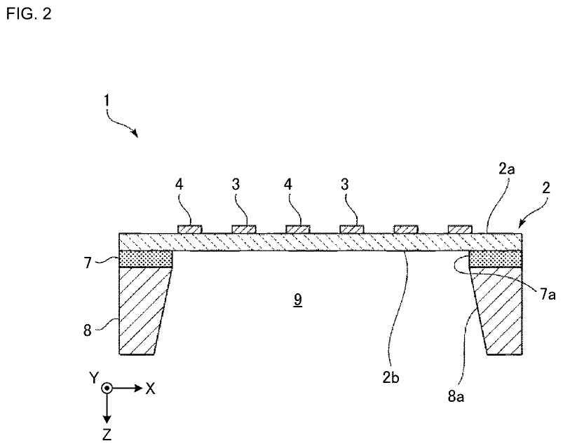

A support substrate 8 is stacked under the second main surface 2b of the piezoelectric layer 2 with an intermediate layer 7 interposed therebetween. The intermediate layer 7 and the support substrate 8 define a support. The intermediate layer 7 and the support substrate 8 have a frame shape and include cavities 7a and 8a, respectively, as shown in FIG. 2. With this structure, a space (air gap) 9 is provided. The space 9 is an example of a hollow portion. The support substrate 8 may include a recessed portion. The space 9 may be defined by a recessed portion provided in the intermediate layer.

The space 9 is provided in order not to interfere with the vibration in an excitation region C of the piezoelectric layer 2. Thus, the support substrate 8 is stacked under the second main surface 2b with the intermediate layer 7 therebetween and is located at a position at which the support substrate 8 does not overlap a region where at least one pair of electrode fingers 3 and 4 is disposed. The support substrate 8 may be stacked directly or indirectly under the second main surface 2b of the piezoelectric layer 2. That is, the provision of the intermediate layer 7 may be omitted. In this case, the support substrate 8 defines the support.

The intermediate layer 7 is made of silicon oxide, for example. Instead of silicon oxide, for example, another suitable insulating material, such as silicon nitride or alumina, may be used for the intermediate layer 7.

The support substrate 8 is made of Si, for example. The plane orientation of Si on the side of the piezoelectric layer 2 may be (100), (110), or (111). Preferably, for example, high-resistivity Si, such as Si having a resistivity of about 4 kΩ or higher, is used. A suitable insulating material or semiconductor material may be used for the support substrate 8. Examples of the material for the support substrate 8 are piezoelectric materials, such as aluminum oxide, lithium tantalate, lithium niobate, and quartz, various ceramic materials, such as alumina, magnesia, sapphire, silicon nitride, aluminum nitride, silicon carbide, zirconia, cordierite, mullite, steatite, and forsterite, dielectric materials, such as diamond and glass, and semiconductor materials, such as gallium nitride.

The above-described plural electrode fingers 3 and 4 and first and second busbars 5 and 6 are made of a suitable metal or alloy, such as Al or an AlCu alloy, for example. In the first example embodiment, the electrode fingers 3 and 4 and the first and second busbars 5 and 6 have, for example, a structure in which an Al film is stacked on a Ti film. A contact layer made of a material other than Ti may be used.

To drive the acoustic wave device 1, an AC voltage is applied to between the multiple electrode fingers 3 and the multiple electrode fingers 4. More specifically, an AC voltage is applied to between the first busbar 5 and the second busbar 6. With the application of the AC voltage, resonance characteristics based on a bulk wave of the thickness shear primary mode excited in the piezoelectric layer 2 can be exhibited.

In the acoustic wave device 1, for example, d/p is set to about 0.5 or smaller, where d is the thickness of the piezoelectric layer 2 and p is the center-to-center distance between adjacent electrode fingers 3 and 4 defining one of multiple pairs of electrode fingers 3 and 4. This can effectively excite a bulk wave of the thickness shear primary mode and obtain high resonance characteristics. More preferably, for example, d/p is about 0.24 or smaller, in which case, even higher resonance characteristics can be obtained.

As in the first example embodiment, when at least one of the number of electrode fingers 3 and the number of electrode fingers 4 is plural, that is, when 1.5 or more pairs of electrode fingers 3 and 4, each pair being formed by an electrode finger 3 and an electrode finger 4, are provided, the center-to-center distance between the adjacent electrode fingers 3 and 4 is the average distance between the adjacent electrode fingers 3 and 4 of the individual pairs.

The acoustic wave device 1 of the first example embodiment is configured as described above. Thus, even if the number of pairs of the electrode fingers 3 and 4 is reduced to miniaturize the acoustic wave device 1, the Q factor is unlikely to be decreased. This is because the acoustic wave device 1 is a resonator which does not require reflectors on both sides and only a small propagation loss is incurred. The reason why the acoustic wave device 1 does not require reflectors is that a bulk wave of the thickness shear primary mode is utilized.

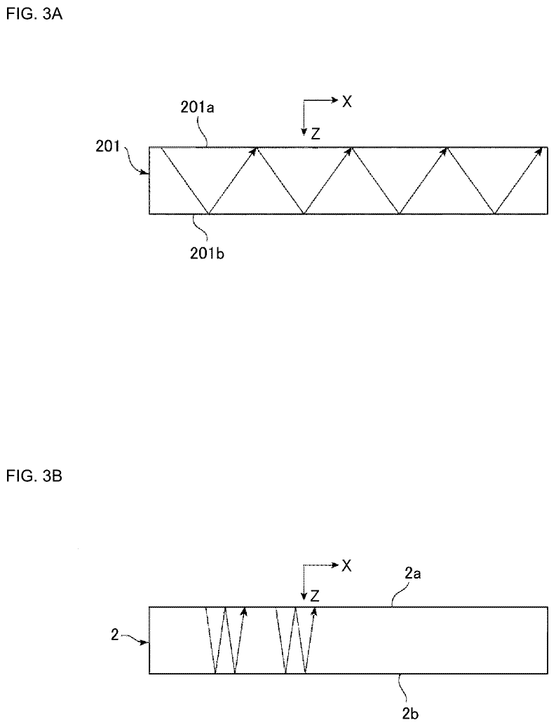

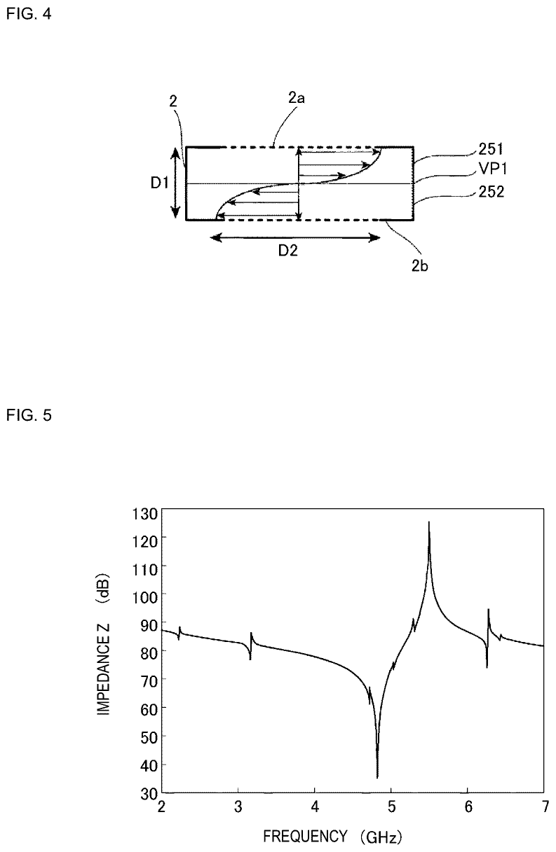

FIG. 3A is a schematic sectional view for explaining a Lamb wave propagating through a piezoelectric layer in a comparative example. FIG. 3B is a schematic sectional view for explaining a bulk wave of the thickness shear primary mode propagating through a piezoelectric layer in an example embodiment. FIG. 4 is a schematic sectional view for explaining the amplitude direction of a bulk wave of the thickness shear primary mode propagating through a piezoelectric layer in an example embodiment.

FIG. 3A shows a Lamb wave propagating through the piezoelectric layer in an acoustic wave device, such as that disclosed in Japanese Unexamined Patent Application Publication No. 2012-257019. As illustrated in FIG. 3A, a wave propagates through a piezoelectric layer 201 as indicated by the arrows. The piezoelectric layer 201 includes a first main surface 201a and a second main surface 201b, and the thickness direction in which the first main surface 201a and the second main surface 201b are linked with each other is the Z direction. The X direction is a direction in which the electrode fingers 3 and 4 of an IDT electrode are arranged. As illustrated in FIG. 3A, a Lamb wave propagates in the X direction. Because of the characteristics of a Lamb wave, while the piezoelectric layer 201 is entirely vibrated, the Lamb wave propagates in the X direction, and thus, reflectors are disposed on both sides to obtain resonance characteristics. Because of these characteristics, a propagation loss occurs in the wave. If the size of the acoustic wave device is reduced, that is, if the number of pairs of electrode fingers is reduced, the Q factor is reduced.

In contrast, as illustrated in FIG. 3B, in the acoustic wave device of the present example embodiment, since the vibration displacement direction is the thickness shear direction, a wave propagates and resonates substantially in a direction in which the first main surface 2a and the second main surface 2b of the piezoelectric layer 2 are linked with each other, namely, substantially in the Z direction. That is, the X-direction components of the wave are much smaller than the Z-direction components. The resonance characteristics are obtained as a result of the wave propagating in the Z direction, and thus, the acoustic wave device does not require reflectors. Thus, a propagation loss, which would be caused by the propagation of a wave to reflectors, does not occur. Even if the number of pairs of the electrode fingers 3 and 4 is reduced to miniaturize the acoustic wave device, the Q factor is unlikely to be reduced.

Regarding the amplitude direction of a bulk wave of the thickness shear primary mode, as shown in FIG. 4, the amplitude direction in a first region 251 included in the excitation region C (see FIG. 1B) of the piezoelectric layer 2, and that in a second region 252 included in the excitation region C, are opposite directions. In FIG. 4, a bulk wave generated when a voltage is applied to between the electrode fingers 3 and 4 so that the potential of the electrode finger 4 becomes higher than that of the electrode finger 3 is schematically illustrated. The first region 251, which is a portion of the excitation region C, is a region between a virtual plane VP1 and the first main surface 2a. The virtual plane VP1 is a plane in a direction perpendicular to the thickness direction of the piezoelectric layer 2 and divides the piezoelectric layer 2 into two regions. The second region 252, which is a portion of the excitation region C, is a region between the virtual plane VP1 and the second main surface 2b.

As discussed above, in the acoustic wave device 1, at least one pair of electrodes defined by electrode fingers 3 and 4 is provided. Since a wave does not propagate in the X direction, it is not necessary that multiple pairs of electrodes defined by electrode fingers 3 and 4 are provided. That is, at least one pair of electrodes is sufficient.

In one example, the electrode finger 3 is an electrode connected to a hot potential, while the electrode finger 4 is an electrode connected to a ground potential. Conversely, the electrode finger 3 may be connected to a ground potential, while the electrode finger 4 may be connected to a hot potential. In the present example embodiment, as described above, at least one pair of electrodes is connected to a hot potential and a ground potential, and more specifically, one electrode of pair is an electrode connected to a hot potential, and the other electrode is an electrode connected to a ground potential. No floating electrode is provided.

FIG. 5 is a graph illustrating an example of the resonance characteristics of an acoustic wave device of an example embodiment. The design parameters of the acoustic wave device 1 that has obtained the resonance characteristics shown in FIG. 5 are as follows.
Piezoelectric layer 2: LiNbO₃ having the Euler angles of (0°, 0°, 90°)
Thickness of piezoelectric layer 2: about 400 nm
Length of excitation region C (see FIG. 1B): about 40 μm
Number of pairs of electrodes constituted by electrode fingers 3 and 4: 21
Center-to-center distance (pitch) between electrode fingers 3 and 4: about 3 μm
Width of electrode fingers 3 and 4: about 500 nm
d/p: about 0.133
Intermediate layer 7: silicon oxide film having a thickness of about 1 μm
Support substrate 8: Si

The excitation region C (see FIG. 1B) is a region where the electrode fingers 3 and 4 overlap each other as seen from the X direction perpendicular or substantially perpendicular to the longitudinal direction of the electrode fingers 3 and 4. The length of the excitation region C is a dimension of the excitation region C in the longitudinal direction of the electrode fingers 3 and 4. The excitation region C is an example of an “overlapping region”.

In the present example embodiment, the center-to-center distance of an electrode pair constituted by electrode fingers 3 and 4 was set to all be equal or substantially equal among multiple pairs. That is, the electrode fingers 3 and 4 were disposed at equal or substantially equal pitches.

As is seen from FIG. 5, despite no reflectors being provided, high resonance characteristics having a fractional bandwidth of, for example, about 12.5% are obtained.

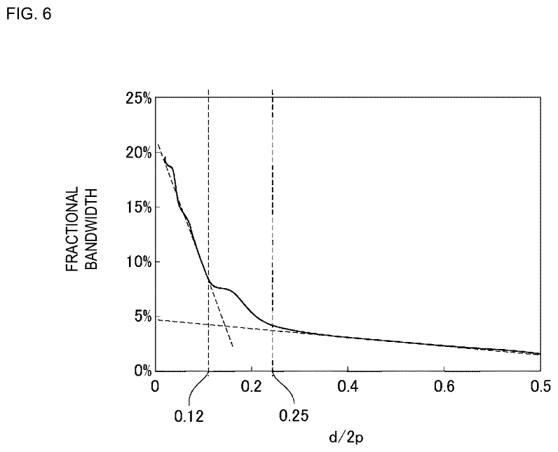

In the present example embodiment, for example, as stated above, d/p is about 0.5 or smaller, and more preferably, d/p is about 0.24 or smaller, where d is the thickness of the piezoelectric layer 2 and p is the center-to-center distance between the electrode fingers 3 and 4. This will be explained below with reference to FIG. 6.

Multiple acoustic wave devices were made in a manner the same as or similar to the acoustic wave device which has obtained the resonance characteristics shown in FIG. 5, except that d/2p was varied among these multiple acoustic wave devices. FIG. 6 is a graph illustrating, regarding the acoustic wave device of the present example embodiment, the relationship between d/2p, where d is the average thickness of the piezoelectric layer 2 and p is the center-to-center distance or the average center-to-center distance between adjacent electrodes, and the fractional bandwidth of the acoustic wave device as a resonator.

As shown in FIG. 6, for example, when d/2p exceeds about 0.25, that is, d/p>about 0.5, the fractional bandwidth remains less than about 5% even if d/p is changed. In contrast, when d/2p≤about 0.25, that is, when d/p≤about 0.5, the fractional bandwidth can be improved to about 5% or higher as long as d/p is changed in this range. It is thus possible to form a resonator having a high coupling factor. When d/2p is about 0.12 or smaller, that is, when d/p is about 0.24 or smaller, the fractional bandwidth can be improved to about 7% or higher. Additionally, if d/p is adjusted in this range, a resonator having an even higher fractional bandwidth can be obtained. It is thus possible to provide a resonator having an even higher coupling factor. Thus, it has been validated that, as a result of setting d/p to about 0.5 or smaller, a resonator utilizing a bulk wave of the thickness shear primary mode and exhibiting a high coupling factor can be provided.

As stated above, at least one pair of electrodes may be only one pair of electrodes. If one pair of electrodes is provided, the above-described center-to-center distance p is the center-to-center distance between the adjacent electrode fingers 3 and 4. If 1.5 or more pairs of electrodes are provided, the center-to-center distance p is the average distance of the center-to-center distances between the adjacent electrode fingers 3 and 4 of the individual pairs.

Regarding the thickness d of the piezoelectric layer 2, if the piezoelectric layer 2 has variations in the thickness, the averaged thickness value may be used.

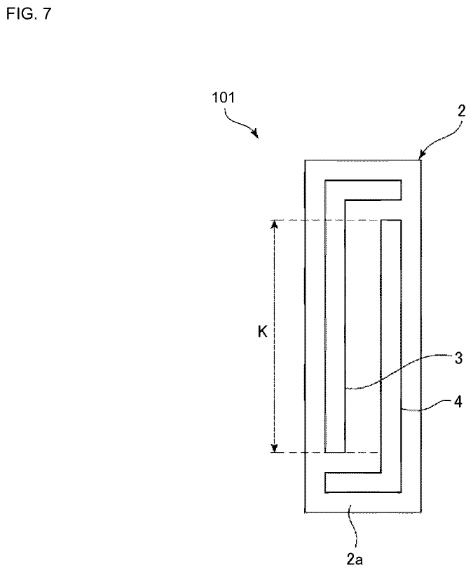

FIG. 7 is a schematic plan view illustrating an example in which a pair of electrodes is provided in the acoustic wave device of the present example embodiment. In an acoustic wave device 101, a pair of electrodes including electrode fingers 3 and 4 is provided on the first main surface 2a of the piezoelectric layer 2. K in FIG. 7 indicates the overlap width of the electrode fingers 3 and 4. As stated above, in an acoustic wave device according to an example embodiment, only one pair of electrodes may be provided. Even in this case, for example, a bulk wave of the thickness shear primary mode can be effectively excited if d/p is about 0.5 or smaller.

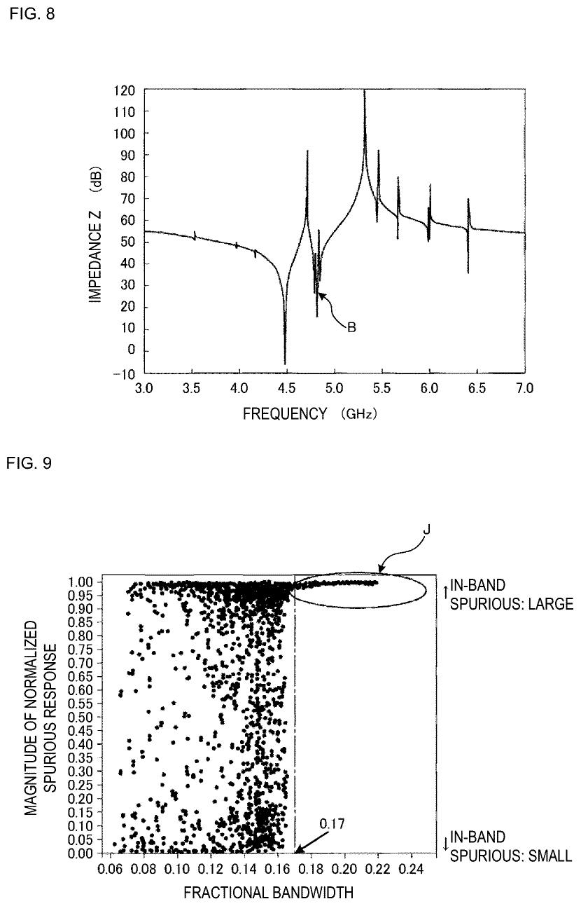

In the acoustic wave device 1, the metallization ratio MR of any one pair of adjacent electrode fingers 3 and 4 among the multiple electrode fingers 3 and 4 to the excitation region C where this pair of electrode fingers 3 and 4 overlap each other as seen in their facing direction preferably satisfies, for example, MR≤about 1.75 (d/p)+0.075. In this case, spurious responses can be effectively reduced. This will be explained below with reference to FIGS. 8 and 9.

FIG. 8 is a reference graph illustrating an example of the resonance characteristics of the acoustic wave device of the present example embodiment. The spurious response indicated by the arrow B is observed between the resonant frequency and the anti-resonant frequency. d/p was set to about 0.08, and the Euler angles of LiNbO₃ were set to (0°, 0°, 90°). The metallization ratio MR was set to about 0.35.

The metallization ratio MR will be explained below with reference to FIG. 1B. In the electrode structure in FIG. 1B, a pair of electrode fingers 3 and 4 will be focused upon, and it is assumed that only this pair is provided. In this case, the portion defined by the long dashed dotted lines is the excitation region C. The excitation region C is a region where the electrode finger 3 overlaps the electrode finger 4, a region where the electrode finger 4 overlaps the electrode finger 3, and a region where the electrode fingers 3 and 4 overlap each other in the region between the electrode fingers 3 and 4, when the electrode fingers 3 and 4 are seen in the direction perpendicular or substantially perpendicular to the longitudinal direction thereof, that is, in the facing direction of the electrode fingers 3 and 4. The area of the electrode fingers 3 and 4 within the excitation region C to the area of the excitation region C is the metallization ratio MR. That is, the metallization ratio MR is a ratio of the area of a metallized portion to the area of the excitation region C.

If multiple pairs of electrode fingers 3 and 4 are provided, the ratio of the areas of the metallized portions included in the total excitation region to the total area of the excitation region is used as the metallization ratio MR.

Many acoustic wave resonators were provided based on the acoustic wave device of the present example embodiment. FIG. 9 is a diagram illustrating the relationship between the fractional bandwidth and the amount of phase shift of the impedance of a spurious response normalized at about 180 degrees as the magnitude of a spurious response. The fractional bandwidth was adjusted by variously changing the film thickness of the piezoelectric layer 2 and the dimensions of electrode fingers 3 and 4. The results shown in FIG. 9 are obtained when a piezoelectric layer 2 made of, for example, Z-cut LiNbO₃ was used. The same or similar results are also obtained if a piezoelectric layer 2 having another cut-angle is used.

A spurious response is as high as about 1.0 in the region defined by the elliptical portion J in FIG. 9. As shown in FIG. 9, when the fractional bandwidth exceeds about 0.17, that is, about 17%, a large spurious response of about 1 or higher is observed within the pass band even if the parameters for the fractional bandwidth are changed. That is, as in the resonance characteristics in FIG. 8, a large spurious response indicated by the arrow B is observed within the pass band. Accordingly, the fractional bandwidth is, for example, preferably about 17% or lower. In this case, the spurious response can be reduced by the adjustment of the film thickness of the piezoelectric layer 2 and the dimensions of electrode fingers 3 and 4, for example.

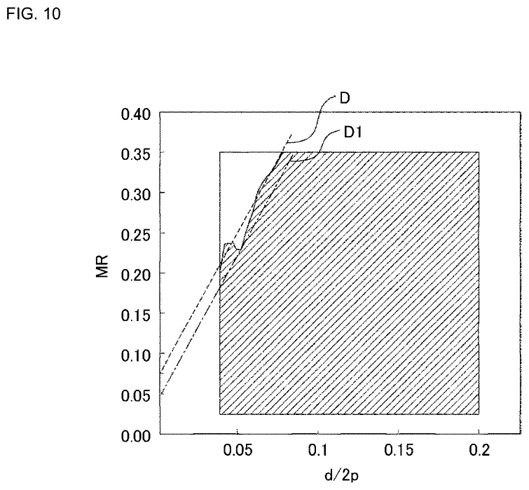

FIG. 10 is a graph illustrating the relationships between d/2p, the metallization ratio MR, and the fractional bandwidth. Based on the acoustic wave device 1 of the present example embodiment, various acoustic wave devices 1 were made by changing d/2p and MR. Then, the fractional bandwidth was measured. The hatched portion on the right side of the broken line D in FIG. 10 is a region where the fractional bandwidth is about 17% or lower. The boundary between the hatched portion and a portion without can be expressed by, for example, MR=about 3.5 (d/2p)+0.075, that is, MR=about 1.75 (d/p)+0.075. Preferably, for example, MR≤about 1.75 (d/p)+0.075, in which case, the fractional bandwidth is likely to be about 17% or lower. More preferably, for example, the region where the fractional bandwidth is about 17% or lower is the region on the right side of the boundary expressed by MR=about 3.5 (d/2p)+0.05, which is indicated by the long dashed dotted line DI in FIG. 10. That is, if MR≤about 1.75 (d/p)+0.05, the fractional bandwidth can reliably be about 17% or lower.

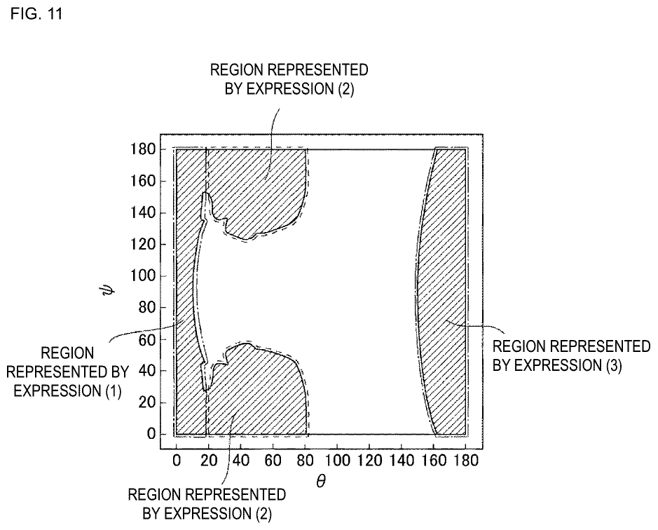

FIG. 11 is a diagram illustrating a map of the fractional bandwidth with respect to the Euler angles (0°, θ, ψ) of LiNbO₃ in a case in which d/p approaches as close to 0 as possible. The hatched portions in FIG. 11 are regions where a fractional bandwidth of at least about 5% or higher is obtained. The ranges of the regions can be approximated to the ranges represented by the following expressions (1), (2), and (3).

$$( 0 ° \pm 10 ° , 0 ° to 20 ° , a desirable angle of ψ ) \qquad Expression ( 1 )$$

$$( 0 ° \pm 10 ° , 20 ° to 80 ° , 0 ° to 60 {° ( 1 - {( θ - 50 )}^{2} / 900 )}^{1 / 2} ) or \qquad Expression ( 2 )$$

$$( 0 ° \pm 10 ° , 20 ° to 80 ° , \{ 180 ° - 60 {° ( 1 - {( θ - 50 )}^{2} / 900 )}^{1 / 2} \} to 180 ° )$$

$$( 0 ° \pm 10 ° , ( 180 ° - 30 {° ( 1 - {( ψ - 90 )}^{2} / 8100 )}^{1 / 2} \} to 180 ° , a desirable angle of ψ ) \qquad Expression ( 3 )$$

When the Euler angles are in the range represented by the above-described expression (1), (2), or (3), a sufficiently wide fractional bandwidth can be obtained, which is preferable.

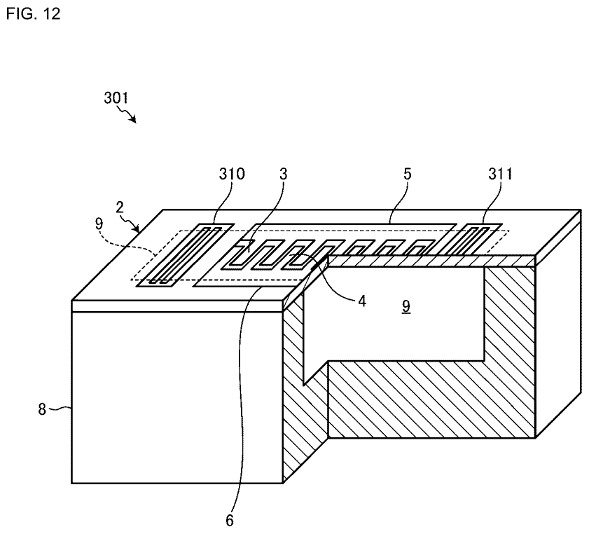

FIG. 12 is a partial cutaway perspective view for explaining an acoustic wave device according to an example embodiment of the present invention. In FIG. 12, the outer peripheral edges of a space 9 are indicated by the broken lines. An acoustic wave device may be an acoustic wave device utilizing a Lamb wave. In this case, as shown in FIG. 12, an acoustic wave device 301 includes reflectors 310 and 311. The reflector 310 is disposed on one side of the electrode fingers 3 and 4 on the piezoelectric layer 2 in the acoustic-wave propagating direction, while the reflector 311 is disposed on the other side of the electrode fingers 3 and 4 in the acoustic-wave propagating direction. In the acoustic wave device 301, a Lamb wave is excited with the application of an AC electric field to the electrode fingers 3 and 4 disposed above the space 9. Since the reflectors 310 and 311 are disposed on both sides of the electrode fingers 3 and 4, resonance characteristics based on the Lamb wave can be obtained.

As described above, in the acoustic wave devices 1 and 101, a bulk wave of the thickness shear primary mode is utilized. In the acoustic wave devices 1 and 101, for example, first and second electrodes 3 and 4 are adjacent electrodes, and d/p is set to about 0.5 or smaller, where d is the thickness of the piezoelectric layer 2 and p is the center-to-center distance between the first and second electrodes 3 and 4. With this configuration, even if the acoustic wave device is reduced in size, the Q factor can be improved.

In the acoustic wave devices 1 and 101, the piezoelectric layer 2 is made of lithium niobate or lithium tantalate, for example. On the first main surface 2a or the second main surface 2b of the piezoelectric layer 2, the first and second electrodes 3 and 4 facing each other in the direction interesting with the thickness direction of the piezoelectric layer 2 are provided. It is preferable that a protection film covers the first and second electrodes 3 and 4.

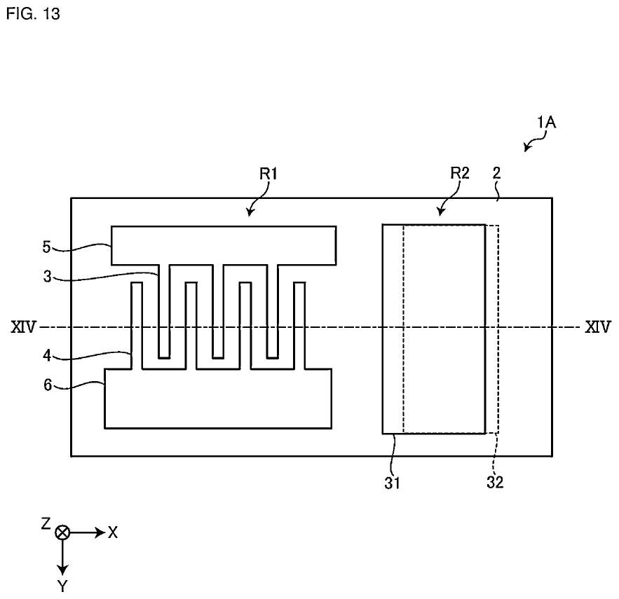

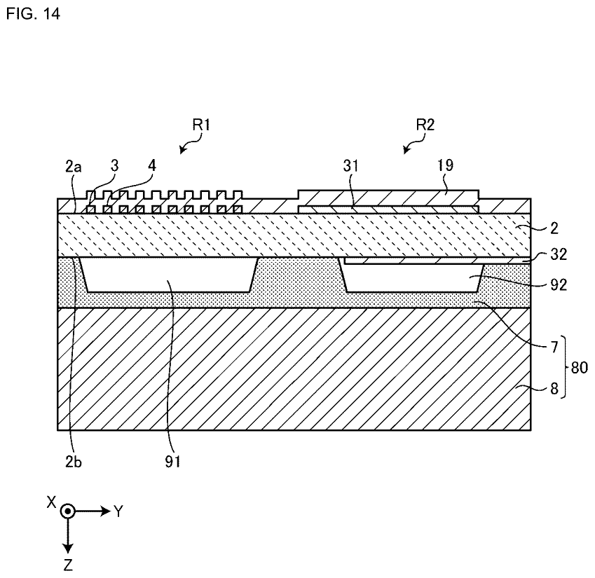

FIG. 13 is a schematic plan view illustrating a portion of an example of an acoustic wave device according to the present example embodiment. FIG. 14 is a sectional view taken along line XIV-XIV. As illustrated in FIGS. 13 and 14, an acoustic wave device 1A according to the present example embodiment is an acoustic wave device including multiple resonators. The multiple resonators include a first resonator R1 and a second resonator R2. The first resonator R1 and the second resonator R2 each include a functional electrode support 80, a piezoelectric layer 2, and a protection film 19.

The functional electrode of the first resonator R1 is an IDT electrode including electrode fingers 3 and 4 and busbar electrodes 5 and 6. The IDT electrode is provided on the first main surface 2a of the piezoelectric layer 2. The IDT electrode may be provided on the second main surface 2b of the piezoelectric layer 2 if the electrode fingers 3 and 4 and the busbar electrodes 5 and 6 are disposed on the same main surface.

The second resonator R2 is a resonator utilizing a bulk wave, that is, for example, it is a BAW (Bulk Acoustic Wave) element. The functional electrode of the second resonator R2 is an upper surface electrode 31 and a lower surface electrode 32. The upper surface electrode 31 is an electrode connected to a hot potential, for example. The upper surface electrode 31 is provided on the first main surface 2a of the piezoelectric layer 2. The lower surface electrode 32 is an electrode connected to a ground potential, for example. The lower surface electrode 32 is provided on the second main surface 2b of the piezoelectric layer 2. At least a portion of the lower surface electrode 32 matches the upper surface electrode 31 in a plan view of the Z direction. The capacitance of the second resonator R2 is determined by the areas of the upper surface electrode 31 and the second surface electrode 32. The capacitance per unit area of the second resonator R2 can be higher than that of the first resonator R1. The upper surface electrode 31 may be connected to a ground potential, while the second surface electrode 32 may be connected to a hot potential.

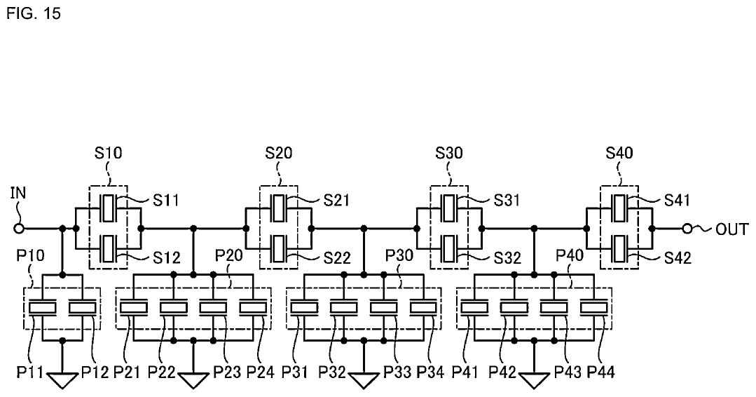

FIG. 15 is a circuit diagram of the acoustic wave device according to the present example embodiment. As illustrated in FIG. 15, the acoustic wave device is, for example, a ladder filter including an input terminal IN, an output terminal OUT, a series arm which couples the input terminal IN and the output terminal OUT, and parallel arms which each couple a node of the series arm and a ground. Multiple resonators included in the acoustic wave device define a ladder filter including series arm resonator sets S10, S20, S30, and S40 provided on the series arm and parallel arm resonator sets P10, P20, P30, and P40 provided on the parallel arms. In FIG. 15, the series arm resonator set S10 includes two series arm resonators S11 and S12 connected in parallel with each other, the series arm resonator set S20 includes two series arm resonators S21 and S22 connected in parallel with each other, the series arm resonator set S30 includes two series arm resonators S31 and S32 connected in parallel with each other, and the series arm resonator set S40 includes two series arm resonators S41 and S42 connected in parallel with each other. The series arm resonator sets S10, S20, S30, and S40 are each electrically connected at one terminal to the input terminal IN and at the other terminal to the output terminal OUT. In FIG. 15, the parallel arm resonator set P10 includes two parallel arm resonators P11 and P12 connected in parallel with each other; the parallel arm resonator set P20 includes four parallel arm resonators P21, P22, P23, and P24 connected in parallel with each other, the parallel arm resonator set P30 includes four parallel arm resonators P31, P32, P33, and P34 connected in parallel with each other, and the parallel arm resonator set P40 includes four parallel arm resonators P41, P42, P43, and P44 connected in parallel with each other. The parallel arm resonator sets P10, P20, P30, and P40 are each electrically connected at one terminal to the input terminal IN and at the other terminal to a ground.

In the present example embodiment, all of the resonators included in the series arm resonator sets S10, S20, S30, and S40 are the first resonators R1. All of the first resonators R1 are series arm resonators disposed on a first path. This can achieve high frequency characteristics of the acoustic wave device 1A.

In the present example embodiment, all of the resonators included in the parallel arm resonator sets P10, P20, P30, and P40 are the second resonators R2. In the present example embodiment, all of the second resonators R2 are parallel arm resonators disposed on a second path. With this configuration, the size of the acoustic wave device 1A can be made smaller than when the acoustic wave device 1A includes only of the first resonators R1. Additionally, the resonant frequency of the parallel arm resonator sets P10, P20, P30, and P40 can be adjusted by changing the areas of the upper surface electrode 31 and the lower surface electrode 32. Thus, for example, it is not necessary to change the film thickness of the protection film 19 and that of the IDT electrode to adjust the resonant frequency, thereby making it possible to manufacture the acoustic wave device 1A more simply.

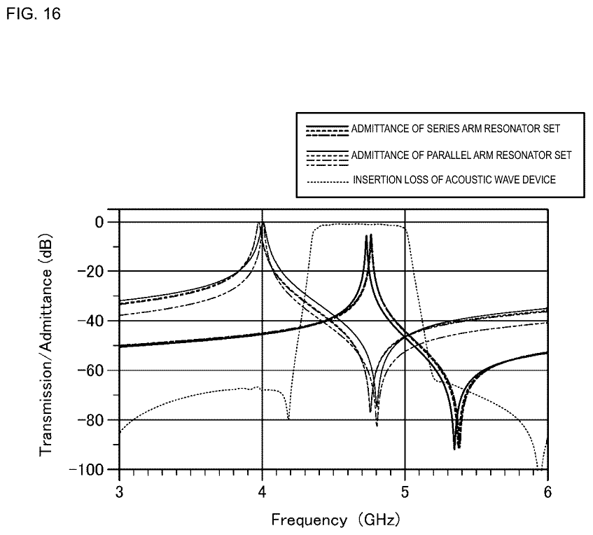

FIG. 16 is a diagram illustrating the frequency characteristics of the acoustic wave device according to the present example embodiment. More specifically, FIG. 16 is a graph illustrating the admittance of the series arm resonator sets S10, S20, S30, and S40, the admittance of the parallel arm resonator sets P10, P20, P30, and P40, and the insertion loss of the acoustic wave device 10A. In the acoustic wave device of the present example embodiment, the largest combined capacitance among the combined capacitances of the series arm resonator sets S10, S20, S30, and S40 is smaller than the smallest combined capacitance among the combined capacitances of the parallel arm resonator sets P10, P20, P30, and P40. The combined capacitance of a resonator set is the capacitance when the resonator set is assumed as a single resonator. That is, the combined capacitance of each of the series arm resonator sets S10, S20, S30, and S40 is smaller than that of any of the parallel arm resonator sets P10, P20, P30, and P40. This can make the resonant frequencies of the series arm resonator sets S10, S20, S30, and S40 higher than those of the parallel arm resonator sets P10, P20, P30, and P40, as shown in FIG. 16, thus achieving high frequency characteristics of the acoustic wave device 1A. Each of the parallel arm resonator sets P10, P20, P30, and P40 is a set of second resonators, which can make the area small. It is thus possible to reduce the size of the acoustic wave device 1A while achieving high frequency characteristics of the acoustic wave device 1A.

The piezoelectric layer 2 is made of rotated Y-cut lithium tantalate or lithium niobate, for example. With this configuration, the first resonator R1 and the second resonator R2 provided on the same piezoelectric layer 2 can utilize a bulk wave of the thickness shear primary mode in close frequencies, thus achieving high frequency characteristics of the acoustic wave device 1A.

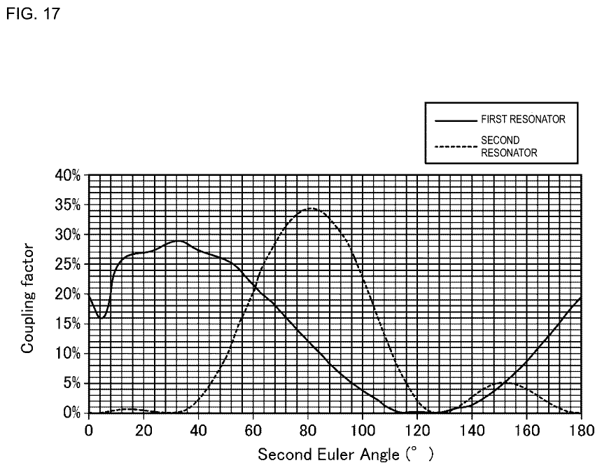

FIG. 17 is a diagram illustrating the coupling factors of the resonators of the acoustic wave device according to the present example embodiment. More specifically, FIG. 17 is a graph illustrating the relationship between the second Euler angle of the piezoelectric layer and the coupling factors of the first resonator R1 and the second resonator R2 disposed on the piezoelectric layer. The second Euler angle of the piezoelectric layer 2 is, for example, preferably about 0° to about 130°. By setting the second Euler angle to this range, the mode coupling factors of the first resonator R1 and the second resonator R2 become greater than 0, thus making it possible to improve the frequency characteristics of the acoustic wave device 1A. More preferably, for example, the second Euler angle of the piezoelectric layer 2 is about 50° to about 70°. By setting the second Euler angle to this range, the coupling factors of the first resonator R1 and the second resonator R2 become close to each other, thus making it possible to further improve the frequency characteristics of the acoustic wave device 1A.

The support 80 includes a support substrate 8 and an intermediate layer 7. The support 80 includes multiple spaces 91 and 92. In a plan view of the Z direction, the space 91 is provided at a position at which at least a portion of the space 91 matches the first resonator R1, while the space 92 is provided at a position at which at least a portion of the space 92 matches the second resonator R2. The multiple spaces may communicate with each other. The space may be provided to at least partially match multiple resonators in a plan view of the Z direction. In the example in FIGS. 14 and 15, the spaces 91 and 92 are provided in the intermediate layer 7 on the side of the piezoelectric layer 2. However, the spaces 91 and 92 may be provided in a different manner. The spaces 91 and 92 may pass through the support 80 in the Z direction or may pass through only the intermediate layer 7 in the Z direction. The support 80 is not limited to the above-described configuration. The support 80 may include only by the support substrate 8 without the intermediate layer 7. In this case, the spaces 91 and 92 may be provided in the support substrate 8 on the side of the piezoelectric layer 2.

The protection film 19 is a film provided on the main surface of the piezoelectric layer 2. The protection film 19 is made of silicon oxide, for example. The protection film 19 is disposed on the entirety or substantially the entirety of the first main surface 2a of the piezoelectric layer 2 so as to cover the first main surface 2a, the electrode fingers 3 and 4, and the upper surface electrode 31. In the example in FIG. 14, the thickness of the protection film 19 is uniform or substantially uniform over the entirety or substantially the entirety of the first main surface 2a of the piezoelectric layer 2. A protection film may be provided on the second main surface.

As described above, an acoustic wave device 1A according to the present example embodiment includes multiple resonators. The multiple resonators include a support 80, a piezoelectric layer 2, and a functional electrode. The support 80 includes a hollow portion (space 9) on a side of one main surface of the support 80. The piezoelectric layer 2 is provided on one main surface of the support 80 and includes a first main surface 2a and a second main surface 2b. The functional electrode is provided on at least one main surface of the piezoelectric layer 2 so as to at least partially match the hollow portion as seen in a thickness direction of the piezoelectric layer 2. The multiple resonators include a first resonator R1 and a second resonator R2. The functional electrode of the first resonator R1 is at least one pair of a first electrode and a second electrode provided on the same main surface of the piezoelectric layer 2. The functional electrode of the second resonator R2 is an upper surface electrode disposed on the first main surface 2a of the piezoelectric layer 2 and a lower surface electrode disposed on the second main surface 2b of the piezoelectric layer 2. With this configuration, the first resonator R1 having high resonance characteristics and the second resonator r2 having a larger capacitance per unit area than the first resonator R1 are provided on the same piezoelectric layer 2. It is thus possible to reduce the size of the acoustic wave device 1A while achieving high frequency characteristics and improved capacitance.

In a preferable example embodiment, the first resonator R1 and the second resonator R2 are able to use a bulk wave of the thickness shear mode. This makes it possible to increase the coupling factor and thus to obtain high resonance characteristics.

In a preferable example embodiment, the acoustic wave device 1A further includes an input terminal IN, an output terminal OUT, a series arm which couples the input terminal IN and the output terminal OUT to each other, and a parallel arm which couples a node on the series arm and a ground to each other. At least one first resonator R1 is provided on the series arm. At least one second resonator R2 is provided on the parallel arm. With this configuration, it is possible to reduce the size of the acoustic wave device while achieving high frequency characteristics.

In a more preferable example embodiment, all of the first resonators R1 are disposed on the series arm. This makes it possible to obtain even higher resonance characteristics.

In a more preferable example embodiment, all of the second resonators R2 are provided on the parallel arm. This makes it possible to further reduce the size of the acoustic wave device while achieving high frequency characteristics.

In a preferable example embodiment, the acoustic wave device 1A further includes an input terminal IN, an output terminal OUT, a series arm which couples the input terminal IN and the output terminal OUT to each other, and a parallel arm which couples a node on the series arm and a ground to each other. A series arm resonator is provided on the series arm, while a parallel arm resonator is provided on the parallel arm. At least one series arm resonator is the first resonator R1. At least one parallel arm resonator is the second resonator R2. With this configuration, it is possible to reduce the size of the acoustic wave device while achieving high frequency characteristics.

In a more preferable example embodiment, all of the series arm resonators are the first resonators R1. This can obtain even higher resonance characteristics.

In a more preferable example embodiment, all of the parallel arm resonators are the second resonators R2. This can make it possible to further reduce the size of the acoustic wave device while achieving high frequency characteristics.

The series arm resonators at the same potential are provided into a series arm resonator set, so that series arm resonator sets S10, S20, S30, and S40 are provided. The parallel arm resonators at the same potential are provided into a parallel arm resonator set, so that parallel arm resonator sets P10, P20, P30, and P40 are provided. In a more preferable example embodiment, the largest combined capacitance among the combined capacitances of the series arm resonator sets is smaller than the smallest combined capacitance among the combined capacitances of the parallel arm resonator sets. This makes it possible to reduce the size of the acoustic wave device while achieving even higher frequency characteristics.

In a preferable example embodiment, the piezoelectric layer 2 is made of rotated Y-cut lithium tantalate or lithium niobate, for example. With this configuration, the first resonator R1 and the second resonator R2 can utilize a bulk wave of the thickness shear primary mode in close frequencies.

In a more preferable example embodiment, the second Euler angle of lithium niobate or lithium tantalate forming the piezoelectric layer 2 is, for example, about 30° to about 130°. This can further improve the frequency characteristics of the acoustic wave device 1A.

In an even more preferable example embodiment, the second Euler angle is, for example, about 50° to about 70°. This can further improve the frequency characteristics of the acoustic wave device 1A.

In a preferable example embodiment, d/p is, for example, about 0.5 or smaller, where d is the thickness of the piezoelectric layer 2 and p is the center-to-center distance between the first electrode 3 and the second electrode 4 adjacent to each other. This can excite a bulk wave of the thickness shear primary mode effectively.

In a more preferable example embodiment, d/p is, for example, about 0.24 or smaller. This can excite a bulk wave of the thickness shear primary mode more effectively.

A region in which the first electrode 3 and the second electrode 4 adjacent to each other overlap each other as seen in a facing direction of the first electrode 3 and the second electrode 4 is an excitation region. In a preferable example embodiment, MR≤about 1.75 (d/p)+0.075 is satisfied, where MR is a metallization ratio of multiple first and second electrodes 3 and 4 to the excitation region. This can effectively reduce spurious responses.

### Second Example Embodiment

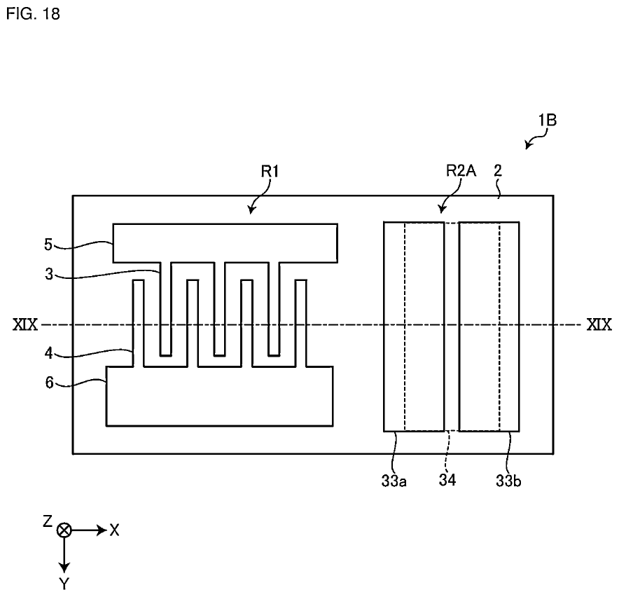

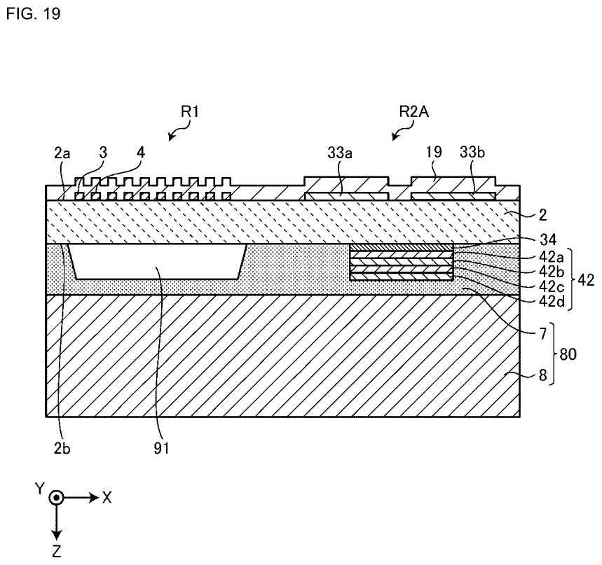

FIG. 18 is a schematic plan view illustrating a portion of an example of an acoustic wave device according to a second example embodiment. FIG. 19 is a sectional view taken along line XIX-XIX. The acoustic wave device of the second example embodiment is different from that of the above-described example embodiment in that it includes a multilayer acoustic film 42 instead of the space 92 for the second resonator R2. An acoustic wave device 1B according to the second example embodiment will be described below with reference to the drawings. An explanation of points similar to those of the acoustic wave device 1A will be omitted.

A second resonator R2A of the second example embodiment includes upper surface electrodes 33a and 33b and a lower surface electrode 34. The upper surface electrode 33a is an electrode connected to a hot potential, for example, while the upper surface electrode 33b is an electrode connected to a ground potential, for example. The upper surface electrodes 33a and 33b are disposed to face each other in the X direction in a plan view of the Z direction. The lower surface electrode 34 is an electrode which is not connected to any other element and is a floating electrode that does not have a specific potential. The lower surface electrode 34 is disposed at a position at which it matches at least part of the upper surface electrodes 33a and 33b in a plan view of the Z direction. The upper surface electrode 33a may be connected to a ground potential, while the upper surface electrode 33b may be connected to a hot potential.

The multilayer acoustic film 42 is provided in the support substrate 80 on the side of the lower surface electrode 34 in the second example embodiment. The multilayer acoustic film 42 is disposed at a position at which it matches at least a portion of the second resonator R2A in a plan view of the Z direction. The multilayer acoustic film 42 has a multilayer structure including low acoustic impedance layers 42a and 42c having a relatively low acoustic impedance and high acoustic impedance layers 42b and 42d having a relatively high acoustic impedance. The low acoustic impedance layers 42a and 42c are dielectric films made of SiO₂, SiOC, or polymer, for example, or metal layers made of Al, for example. The high acoustic impedance layers 42b and 42d are metal layers made of W, Pt, or Mo, for example, or dielectric layers made of tantalum oxide, tungsten oxide, or aluminum nitride, for example. The use of the multilayer acoustic film 42 can trap a bulk wave of the thickness shear primary mode inside the piezoelectric layer 2 without using the space 92. In the multilayer acoustic film 42, the number of low acoustic impedance layers 42a and 42c and the number of high acoustic impedance layers 42b and 42d are not limited to particular numbers. Any number of low acoustic impedance layers and any number of high acoustic impedance layers may be used if at least one high acoustic impedance layer is provided farther away from the piezoelectric layer 2 than low acoustic impedance layers are.

The above-described example embodiments are provided to facilitate the understanding of the present invention, but are not intended to be exhaustive or to limit the present invention to the precise configurations disclosed. Modifications and/or improvements may be made without departing from the spirit and scope of the present invention, and equivalents of the present invention are also encompassed in the disclosure.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a plurality of resonators including:
a support including a hollow portion on a side of one main surface of the support;
a piezoelectric layer on a side of the main surface of the support and including first and second main surfaces; and
a functional electrode on a side of at least one main surface of the piezoelectric layer so as to at least partially match the hollow portion as seen in a thickness direction of the piezoelectric layer; wherein
the plurality of resonators include first and second resonators;
the functional electrode of the first resonator includes at least one pair of a first electrode and a second electrode on the same main surface of the piezoelectric layer; and
the functional electrode of the second resonator includes an upper surface electrode and a lower surface electrode, the upper surface electrode being provided on the first main surface of the piezoelectric layer, the lower surface electrode being provided on the second main surface of the piezoelectric layer.

2. The acoustic wave device according to claim 1, wherein the first and second resonators are structured to generate a bulk wave of a thickness shear mode.

3. The acoustic wave device according to claim 1, further comprising:
an input terminal;
an output terminal;
a series arm coupling the input terminal and the output terminal to each other; and
a parallel arm coupling a node on the series arm and a ground to each other; wherein
at least one of the first resonators is provided on the series arm; and
at least one of the second resonators is provided on the parallel arm.

4. The acoustic wave device according to claim 3, wherein all of the first resonators are provided on the series arm.

5. The acoustic wave device according to claim 3, wherein all of the second resonators are provided on the parallel arm.

6. The acoustic wave device according to claim 1, further comprising:
an input terminal;
an output terminal;
at least one series arm coupling the input terminal and the output terminal to each other; and
at least one parallel arm coupling a node on the series arm and a ground to each other; wherein
the at least one series arm resonator is provided on the series arm;
the at least one a parallel arm resonator is provided on the parallel arm;
the at least one series arm resonator includes the first resonator; and
the at least one parallel arm resonator includes the second resonator.

7. The acoustic wave device according to claim 6, wherein all of the at least one series arm resonator include the first resonator.

8. The acoustic wave device according to claim 6, wherein all of the at least one parallel arm resonator includes the second resonator.

9. The acoustic wave device according to claim 6, wherein
the series arm resonators at a same or substantially a same potential define a series arm resonator set, and the parallel arm resonators at a same or substantially a same potential define a parallel arm resonator set; and
of combined capacitances of series arm resonator sets and combined capacitances of parallel arm resonator sets, a largest combined capacitance among the combined capacitances of the series arm resonator sets is smaller than a smallest combined capacitance among the combined capacitances of the parallel arm resonator sets.

10. The acoustic wave device according to claim 1, wherein the piezoelectric layer includes rotated Y-cut lithium tantalate or lithium niobate.

11. The acoustic wave device according to claim 10, wherein a second Euler angle of the lithium niobate or the lithium tantalate of the piezoelectric layer is about 30° to about 130°.

12. The acoustic wave device according to claim 11, wherein the second Euler angle is about 50° to about 70°.

13. The acoustic wave device according to claim 1, wherein d/p is about 0.5 or smaller, where d is a thickness of the piezoelectric layer and p is a center-to-center distance between the first electrode and the second electrode adjacent to each other.

14. The acoustic wave device according to claim 13, wherein the d/p is about 0.24 or smaller.

15. The acoustic wave device according to claim 1, wherein
a region in which the first electrode and the second electrode adjacent to each other overlap each other as seen in a facing direction of the first electrode and the second electrode is an excitation region; and
MR≤about 1.75 (d/p)+0.075 is satisfied, where MR is a metallization ratio of a plurality of the first and second electrodes to the excitation region.

16. The acoustic wave device according to claim 1, wherein a thickness of the piezoelectric layer is about 50 nm to about 1000 nm.

17. The acoustic wave device according to claim 1, wherein a center-to-center distance between the first electrode and the second electrode is about 1 μm to about 10 μm.

18. The acoustic wave device according to claim 1, wherein a width of each of the first and second electrodes is about 150 nm to about 1000 nm.

19. The acoustic wave device according to claim 1, wherein the support includes a support substrate and an intermediate layer between the piezoelectric layer and the support substrate.
